(19) United States
(12) Patent Application Publication
(10) Pub. No.: US 2015/0200336 A1
(43) Pub. Date: Jul. 16, 2015

(54) WAFER LEVEL CONTACT PAD STANDOFFS WITH INTEGRATED REFLECTOR

(71) Applicant: CREE, INC., Durham, NC (US)

(72) Inventors: Chandon Bhat, Goleta, CA (US); Fan Zhang, Goleta, CA (US); Theodore Lowes, Lompoc, CA (US); Peter Andrews, Durham, NC (US)

(73) Assignee: CREE, INC., Durham, NC (US)

(21) Appl. No.: 14/201,490

(22) Filed: Mar. 7, 2014

Related U.S. Application Data
(63) Continuation-in-part of application No. 14/152,829, filed on Jan. 10, 2014.

(51) Int. Cl. H01L 33/48; H01L 33/62; H01L 33/54; H01L 33/56; H01L 33/46; H01L 33/50

(52) U.S. Cl. CPC H01L 33/486; H01L 33/46; H01L 33/507; H01L 33/54; H01L 33/56; H01L 33/62; H01L 2933/0025; H01L 2933/0033; H01L 2933/0058; H01L 2933/0066

(57) ABSTRACT

This disclosure relates to surface mount devices, such as light emitting devices, and methods of manufacture thereof, including recessed contact pads in relation to a mount surface, such that contact bumps and a reflective material are disposed to form a planar mounting surface. Embodiments according to the present disclosure include a light emitting device, wherein the device comprises at a reflective layer, forming at least a portion of a mounting surface. The device also includes one or more contact pads on the device, such that the contact pads are recessed in relation to the reflective layer. Contact bumps are formed on the contact pads, protruding beyond the contact pads, wherein the contact bumps compose at least a portion of the mounting surface. Methods of manufacture including methods utilizing virtual wafer structures are also disclosed.

### CROSS REFERENCE TO RELATED APPLICATIONS

This application claims the benefit of provisional U.S. Patent Application No. 64/941,369, filed on Feb. 18, 2014, entitled “WAFER LEVEL CONTACT PAD STANDOFFS WITH INTEGRATED REFLECTOR.” This application also claims the benefit of and is a continuation in part of U.S. patent application Ser. No. 14/152,829, filed on Jan. 10, 2014, entitled “WAFER LEVEL CONTACT PAD SOLDER BUMPING FOR SURFACE MOUNT DEVICES WITH NON-PLANAR RECESSED CONTACTING SURFACES.” The disclosures of these applications are hereby incorporated by reference.

### BACKGROUND OF THE INVENTION

1. Field of the Invention

Described herein are devices and methods relating to surface mount devices, such as light emitting diode (LED) chips and components, including LED chips, which have a planar mount surface including contact pads.

2. Description of the Related Art

Surface mount devices, such as LED-based light emitting devices, are increasingly being used in lighting/illumination applications. Semiconductor LEDs are widely known solid-state lighting elements that are capable of generating light upon application of voltage thereto. LEDs generally include a diode region having first and second opposing surfaces, and including therein an n-type layer, a p-type layer and a p-n junction. An anode contact ohmically contacts the p-type layer and a cathode contact ohmically contacts the n-type layer. In some cases, the diode region may be epitaxially formed on a substrate, such as a sapphire, silicon, silicon carbide, gallium arsenide, gallium nitride, etc., or growth substrate, but the completed device may have the substrate removed. The diode region may be fabricated, for example, from silicon carbide, gallium nitride, gallium phosphide, aluminum nitride and/or gallium arsenide-based materials and/or from organic semiconductor-based materials. In other configurations, it may be possible for the device to never include a substrate, such as if grown or processed on a virtual wafer.

Submounts are generally used in LED devices to interpose an LED chip and a printed circuit board. The submount may change the contact configuration of the LED chip to be compatible with the pads of the printed circuit board. The submount may also be used to support a phosphor layer or an encapsulating dome that surrounds the LED chip. The submount may also provide other functionality. Thus, a submount may include a receiving element onto which an LED chip is mounted using conventional die-attach techniques, to interface the LED chip and a printed circuit board. A submount generally has a thickness of at least 100 μm, and in some embodiments at least 150 μm, and in other embodiments at least 200 μm, and generally includes traces (such as on ceramic panels) and/or leads (such as in a Plastic Leaded Chip Carrier (PLCC) package).

The color or wavelength emitted by an LED is largely dependent on the properties of the material from which it is generated, such as the bandgap of the active region. LEDs have been built to emit light in a range of colors in the visible spectrum including red, yellow, green, and blue. Other LEDs emit in the ultraviolet (UV) range of the electromagnetic spectrum. It is often desirable to incorporate phosphors into a LED to tailor the emission spectrum by converting all or a portion of the light from the LED before it is emitted as it passes through. For example, in some blue LEDs, a portion of the blue light is “downconverted” to yellow light. Thus, the LED emits a combination of blue and yellow light to generate a spectrum that appears white to the human eye. This is known as a blue-shifted yellow (BSY) LED device. As used herein, the term “phosphor” is used generically to indicate any photoluminescent material.

Because of the above issues, the application of a conversion layer to an LED chip is typically done at the package level after the LEDs have already been singulated and subsequently bonded to an electronic element, such as a PCB. However, applying a conversion material at the package level rather than the wafer level is a less efficient manufacturing process, as it is much easier and cost effective to coat multiple LED chips simultaneously at the wafer level.

It is desirable to complete as many steps as possible at the wafer level rather than at the package level, as it is more efficient to do so for manufacturing purposes. For surface mount devices, which have recessed contact pads in relation to the mounting surface of the device, these contacts to the mount surface at this time are being formed by adding gull wing type attachments to the contact pads at a package level. Alternatively, large amounts of metal paste are added to the mount surface in the hopes that during the mounting process this metal paste will enter the recessed areas and make contact with the contact pads. Unfortunately, this process can be unreliable, include low yields with regard to successful bonding, and can result in imbalanced devices or unbalanced amounts of material on each contact pad of the device. It would be desirable to utilize a more reliable and controlled process to create contacts, preferably at the wafer level, which could also increase manufacturing efficiencies.

The device 101 of FIG. 1 shows a cross-sectional view of a die on a substrate 102. The die includes a light emission area 120 and an optional substrate 110. The die also includes a contact pad 160 and bond metal 162. The die is attached to substrate 102 via the bond metal 162 and contact pad 160. A phosphor 150 may be added over the device for light conversion. As shown by the arrows in region 104, light which is emitted from the edges of the die, between the phosphor 150 and the bond metal, may be lost or absorbed as this light can be reflected up and back into the chip by the substrate 102 or may be absorbed by the contact pad 160 or bond metal 162. Therefore, light emission in this area may not be desirable as there will be negative impacts to efficiency.

### SUMMARY OF THE INVENTION

The present invention discloses new devices and methods for fabricating surface mount or solid state devices, such as LED chips and providing bumped contacts for recessed contact pads, in relation to a reflective layer, at the wafer level. One embodiment of a device according to the present disclosure includes a surface mount device, comprising a mounting surface and a reflective layer, wherein the reflective layer comprises at least a portion of the mounting surface. The device also includes one or more contact pads disposed on the device, such that the contact pads are recessed in relation to the reflective layer. Additionally, the device includes contact bumps formed on the contact pads, the contact bumps protruding beyond the contact pads, such that the contact bumps comprise at least a portion of the mounting surface. In some embodiments, this mounting surface is planar. In some cases the contact-mounting surface is electo-plated to form a contact pad that has a thickness sufficient to accommodate the reflective layer (>50 um).

A second embodiment according to the present disclosure may include a light emitting device wafer, comprising a plurality of light emitting devices, the devices comprising a mounting surface and a reflective layer, wherein the reflective layer comprises at least a portion of the mounting surface. The devices also may comprise one or more contact pads disposed on the device, such that the contact pads are recessed in relation to the reflective layer and contact bumps formed on the contact pads, the contact bumps protruding beyond the contact pads, wherein the contact bumps comprise at least a portion of the mounting surface.

The disclosure also discusses methods of forming such devices, such that one embodiment of a method according to the present disclosure includes a method of fabricating wafer level light emitting device chips, comprising providing a plurality of light emitting devices as a wafer, the devices comprising at least a contact pad on a surface of the device. The method further comprises providing a stencil over the devices and providing a solder material over the stencil. Next, the method includes disposing the solder material over the contact pads and forming the solder material into contact bumps in contact with the contact pads, the contact bumps protruding beyond the surface. Additionally, the method includes providing a reflective material at least partially covering the surface and at least partially surrounding the contact bumps, wherein the reflective material forms at least a portion of a mounting surface, further wherein the contact pads are recessed in relation to at least a portion of the mounting surface.

Yet another method according to an embodiment of the present disclosure includes a method of fabricating level light emitting device chips, comprising providing a light emitting device, the device comprising at least a contact pad on a surface of the device. The method additionally includes disposing a solder material over the contact pads and forming the material into contact bumps in contact with the contact pads, such that the contact bumps protrude beyond the surface. Also, the method includes providing a reflective material at least partially covering the surface and at least partially surrounding the contact bumps, wherein the reflective material forms at least a portion of a mounting surface, further wherein the contact pads are recessed in relation to at least a portion of the mounting surface.

Various embodiments described herein may arise from a recognition that other techniques may be used to provide the reflective material and/or modify the contact sizes or spacing for greater compatibility with printed circuit board pads and/or other techniques may be used to provide a phosphor layer and/or a dome or other encapsulation layer on an LED chip without the need to provide a separate submount or interposer between the LED chip and the printed circuit board. For example, contact bumps may be formed over the anode and/or cathode contacts of an LED chip to increase the effective contact height of the anode and cathode contacts.

These and other further features and advantages of the invention would be apparent to those skilled in the art from the following detailed description, taken together with the accompanying drawings, wherein like numerals designate corresponding parts in the figures, in which:

### BRIEF DESCRIPTION OF THE DRAWINGS

FIG. 1 is a cross-sectional side view of a prior art device;

FIG. 2a is a cross-sectional side view of a device according to an embodiment of the present disclosure;

FIG. 2b is a cross-sectional side view of a device according to another embodiment of the present disclosure;

FIG. 2c is a cross-sectional side view of a device according to another embodiment of the present disclosure;

FIG. 2d is a cross-sectional side view of a device according to another embodiment of the present disclosure;

FIG. 2e is a cross-sectional side view of a device according to another embodiment of the present disclosure;

FIG. 2f is a cross-sectional side view of a device according to another embodiment of the present disclosure;

FIGS. 3a-3c are cross-sectional side views of a wafer or virtual wafer of devices, showing a method of forming contact bumps, according to an embodiment of the present disclosure;

FIGS. 4a and 4b are charts showing lumens per watt gains that can be achieved when employing a reflective layer, according to an embodiment of the present disclosure;

FIG. 5 is a cross-sectional side view of a device before contact bump formation, according to another embodiment of the present disclosure;

FIG. 6 is a cross-sectional side view of a device after contact bump formation, according to another embodiment of the present disclosure;

FIG. 7 is a cross-sectional side view of a device after reflective layer placement, according to another embodiment of the present disclosure;

FIG. 8 is a cross-sectional side view of a device after mount surface grinding, according to another embodiment of the present disclosure;

FIG. 9 is a bottom view of a wafer without a reflective layer, according to another embodiment of the present disclosure;

FIG. 10 is a bottom view of a wafer with a reflective layer, according to another embodiment of the present disclosure;

FIG. 11 is a bottom view of a wafer after reflective layer placement, according to another embodiment of the present disclosure;

FIG. 12 is a bottom view of a wafer after mount surface grinding to expose contact bumps, according to another embodiment of the present disclosure;

FIG. 13 is a bottom view of a wafer polished or ground to varying degrees for demonstration, according to another embodiment of the present disclosure;

FIG. 14 is a side perspective view of a device according to another embodiment of the present disclosure;

FIG. 15 is a bottom perspective view of the device of FIG. 14, according to another embodiment of the present disclosure;

FIG. 16 is a cross-sectional side view of a mount surface of a device according to another embodiment of the present disclosure;

FIG. 17 is a cross-sectional side view of a chip mounted to a submount which has undergone the process shown in FIGS. 5-8 according to an embodiment of the present disclosure;

FIG. 18 is a cross-sectional side view of a chip mounted to a submount with room for a reflective undercoating according to an embodiment of the present disclosure;

FIG. 19 is a cross-sectional side view of a chip mounted to a submount with room for a reflective undercoating according to another embodiment of the present disclosure.

### DETAILED DESCRIPTION OF THE INVENTION

The present disclosure will now set forth detailed descriptions of various embodiments. These embodiments provide methods and devices pertaining to surface mount devices and solid state devices, such as light emitting devices, various light emitters, LED chips, LED wafers, LED components, and methods of manufacture thereof. Embodiments incorporating features of the present invention allow for the efficient addition of contact bumps to devices with reflective coatings that would otherwise result in recessed contacts. Some embodiments of this disclosure may refer to contact pads with contact extensions, it should be understood that the contact extensions may be contact bumps or any other type of extension. For simplicity, the term contact bumps may refer to other types of extensions as well. Additionally, the term contact may refer to both the term contact pad and extension, or the combination of both.

In some embodiments incorporating features of the present invention, solid state devices, such as LED chips or packages, are provided with contact bumps arranged such that they protrude from or are exposed at the bottom or mounting surface of the device, enabling the contact bumps to make contact with mount surfaces. The contact bumps are provided in contact with contact pads on the device. The mounting surface of the device is the surface, which will be adjacent to the mount surface that the device is being mounted to. After the contact bumps are provided, the mounting surface of the device is covered or flooded with a white or reflective material. The white or reflective material at least partially covers the contact bumps and may be disposed on all sides, or some sides, of the contact bumps. Next, if needed, the bottom of the device is polished or ground to expose the contact bumps for mounting, or to provide a substantially uniform, planar, or even mounting surface.

In some embodiments, according to the present invention, the contact bumps are formed at the wafer level by a process which utilizes a stencil, the contact bump material, and a squeegee or blade for distributing the material in equal amounts to the device through the stencil. This equal distribution allows contact bumps of uniform size to be made at the wafer level for a plurality of devices. Embodiments according to the present disclosure can allow for devices to be efficiently provided with contact bumps at a wafer, “virtual wafer” or array level. The contact bumps may also be formed by other methods such as wave soldering, ink jetting, sputtering, provided via preforms, gold-wire-ball bumping, or by evaporation, such as CVD or PVD. In some embodiments, contact bumps may also be formed by electroplating a metal, such as Nickel, on the contact to a thickness, such as 50 um (−20 um +50 um). The thickness of this metal may range from 15 um to 150 um. Electroplating (or similar techniques) may be accomplished at the wafer level with very little cost and achieve a “wafer-fab-quality-bumped” contact effect. This metallization build up can then be further electroplated or electroless deposited for a termination, which is solderable and oxidation friendly. This technique can also be used to extend contact bumps past the reflective layer and in reverse to build up substrates so that a chip can be placed, such that a reflective ring can be wicked underneath for light extraction benefits.

Embodiments incorporating features of the present invention can also include various structures to improve stability of a light emitter array, such as an LED chip array, during the manufacturing process, such as additional adhesive and/or virtual wafers comprising a silicone support, a glass support and/or a frame structure.

Some embodiments of light emitter components according to the present disclosure utilize a reflective material, such as a white diffusive paint or coating, metal reflector, or other type of reflective surface, to further improve light extraction and emission uniformity. This reflective layer may be applied to, and form a portion of, the bottom or mounting surface of the device. The thickness of this layer may, at least in part, cover or surround contact bumps placed on the contact pads, such that the contact pads are recessed in relation to the highest portions of the mounting surface of the device including the reflective layer, as the addition of the reflective layer may increase the height of the surface. In other embodiments, the contact pads may be recessed due to other reasons.

In the description that follows, numerous details are set forth in order to provide a thorough understanding of the invention. It will be appreciated by those skilled in the art that variations of these specific details are possible while still achieving the results of the invention. Well-known elements and processing steps are generally not described in detail in order to avoid unnecessarily obscuring the description of the invention.

Embodiments of the invention are described herein with reference to illustrations that are schematic illustrations of embodiments of the invention. As such, the actual size, components and features can be different, and variations from the shapes of the illustrations as a result, for example, of technological capabilities, manufacturing techniques and/or tolerances are expected. Embodiments of the invention should not be construed as limited to the particular shapes or components of the regions illustrated herein but are to include deviations in shapes/components that result, for example, from manufacturing or technological availability. The regions illustrated in the figures are schematic in nature and their shapes are not intended to illustrate the precise shape or functionality of a feature of a device and are not intended to limit the scope of the invention. In addition, components may be shown as one unit but may instead be a collection of components or units, or a collection of components or units may exist as one unit.

Throughout this description, the preferred embodiment and examples illustrated should be considered as exemplars, rather than as limitations on the present invention. As used herein, the term “invention,” “device,” “method,” “present invention,” “present device” or “present method” refers to any one of the embodiments of the invention described herein, and any equivalents. Furthermore, reference to various feature(s) of the “invention,” “device,” “method,” “present invention,” “present device” or “present method” throughout this document does not mean that all claimed embodiments or methods must include the referenced feature(s).

It is also understood that when an element or feature is referred to as being “on”, “contacting” or “adjacent” to another element or feature, it can be directly on or adjacent to the other element or feature or intervening elements or features may also be present. It is also understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “outer”, “above”, “lower”, “below”, “horizontal”, “vertical” and similar terms, may be used herein to describe a relationship of one feature to another. It is understood that these terms are intended to encompass different orientations in addition to the orientation depicted in the figures.

Although the terms first, second, etc. may be used herein to describe various elements or components, these elements or components should not be limited by these terms. These terms are only used to distinguish one element or component from another element or component. Thus, a first element or component discussed below could be termed a second element or component without departing from the teachings of the present invention. As used herein, the term “and/or” includes any and all combinations of one or more of the associated list items.

The terminology used herein is for describing particular embodiments only and is not intended to be limiting of the invention. As used herein, the singular forms “a,” “an,” and “the” are intended to include the plural forms as well, unless the context clearly indicates otherwise. It will be further understood that the terms “comprises,” “comprising,” when used herein, specify the presence of stated features, integers, steps, operations, elements, and/or components, but do not preclude the presence or addition of one or more other features, integers, steps, operations, elements, components, and/or groups thereof.

It is noted that the terms “layer” and “layers” are used interchangeably throughout the application. A person of ordinary skill in the art will understand that a single “layer” of material may actually comprise several individual layers of material. Likewise, several “layers” of material may be considered functionally as a single layer. In other words, the term “layer” does not denote a homogenous layer of material. A single “layer” may contain various material concentrations and compositions that are localized in sub-layers. These sub-layers may be formed in a single formation step or in multiple steps. Unless specifically stated otherwise, it is not intended to limit the scope of the invention as embodied in the claims by describing an element as comprising a “layer” or “layers” of material.

Though the reflective layer, contact pad and bump structures described herein may be used with any device, surface mount device, or solid state device, various embodiments described herein can relate to LED components. Some of these components may be arranged such that they eliminate the need for a submount or interposer between an LED chip and a printed circuit board on which an LED chip is mounted, thereby reducing the cost, size and/or complexity of these devices. Other embodiments may relate to LED packages, chips, or wafers.

Moreover, LED chips that do not include a submount may be placed on a tape, coated with a phosphor layer and, optionally, also coated with a transparent layer that is free of phosphor, removed from the tape and then soldered to a printed circuit board without the need for an intervening submount. Other techniques may also be used to provide submount-free LED components and methods of manufacturing the same, according to various embodiments described herein. A wafer of the submount-free devices consists of a monolithic periodic array of chips. In some embodiments, these include an integrated wavelength converter and integrated encapsulant, but no substrate or submount on the bottom, such as a PCB or ceramic carrier.

In order for these devices to achieve the performance parity with traditional components, or to optimize or improve their performance, it may be desirable to at least partially coat the bottom of the device or wafer with a reflector or highly reflective material. In some embodiments, the thickness of this reflective material may be 5-200 microns. In other embodiments, this thickness may be 25-150 microns. In yet other embodiments, other thicknesses may be used to achieve the desired reflectivity. This reflective material coating encroaches inside the outer periphery of the chip, up to, and in some embodiments surrounding the contact pads. In some embodiments this material is applied after the contact bumps have been formed and the reflective material may at least partially surround and/or partially cover the contact bumps.

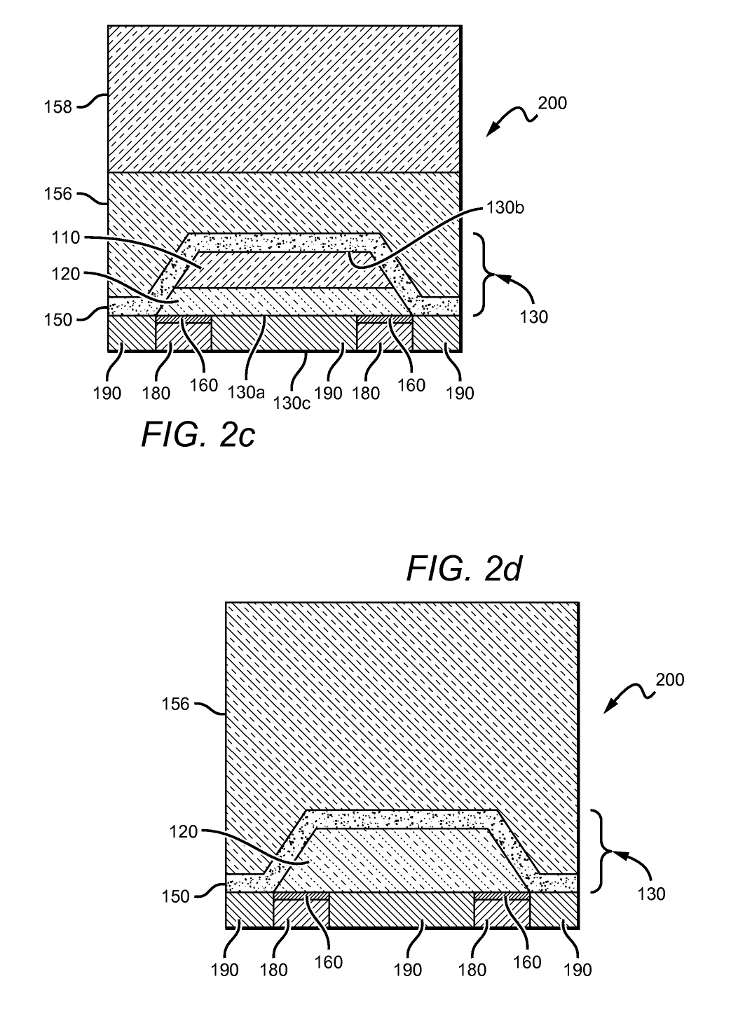

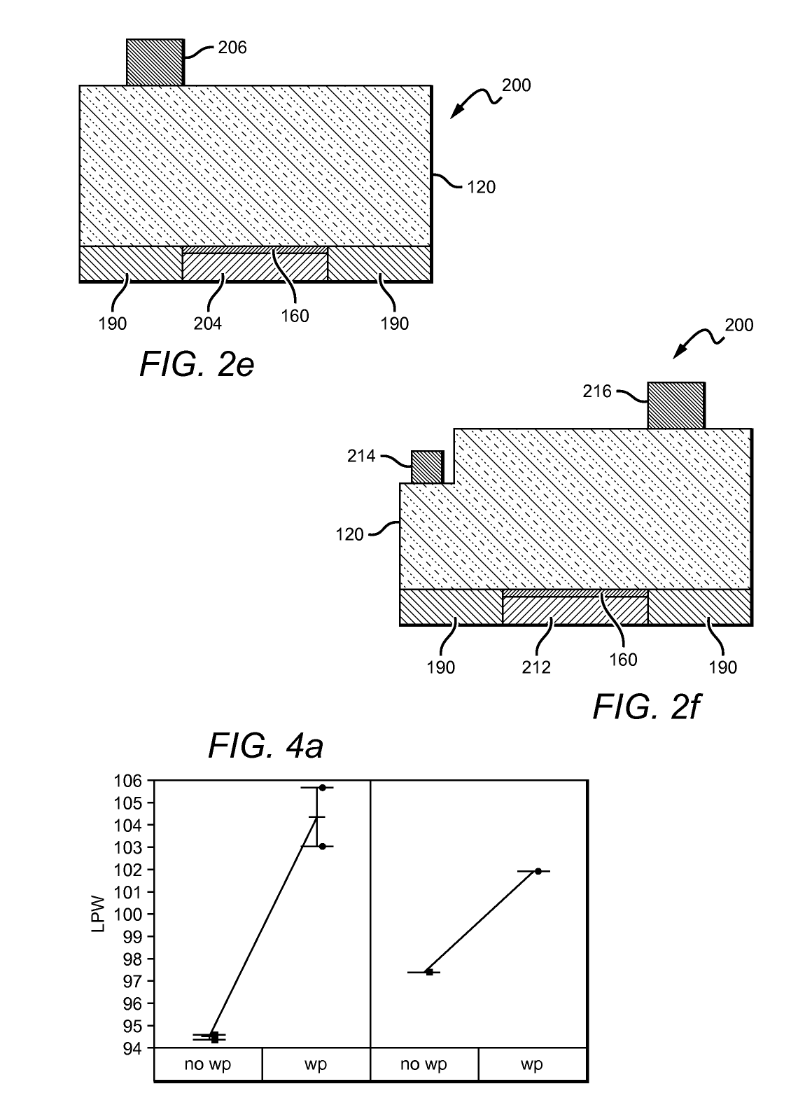

FIGS. 2a-2f are cross-sectional views of a light emitting device according to various embodiments described herein. Features similar to those found in other figures are referred to by the same numerals for ease of reference. Referring now to FIG. 2a, the light emitting device 200 includes a Light Emitting Diode (LED) chip 130 having first and second opposing faces 130a and 130b, respectively. The LED chip 130 includes a diode region 120 that includes therein an n-type layer and a p-type layer. Each of these n-type and p-type layers may include one or more of each layer. These layers may have different compositions and thicknesses as is known to those in the art. Any reference to the n-type layer or p-type layer may be referencing one or more of the respective layers. Other layers or regions may also be provided in the diode region 120, which may include quantum wells, buffer layers, etc., that are understood in the art and need not be described herein. Moreover, the n-type layer and the p-type layer may be adjacent to one another to form a p-n junction or may be spaced apart from one another. The diode region 120 may also be referred to herein as an “LED epi region”, because it is typically formed epitaxially on a substrate. For example, a Group III-nitride based LED epi 120 may be formed on a silicon carbide growth substrate. In some embodiments, the growth substrate may be present in the finished product. In other embodiments, the growth substrate may be removed. In still other embodiments, another substrate may be provided that is different from the growth substrate, and the other substrate may be bonded to the LED epi region after removing the growth substrate.

As also shown in FIG. 2a, a transparent substrate 110, such as a transparent silicon carbide growth substrate or a transparent sapphire growth substrate, may be provided on the diode region 120. As used herein, a layer or region of an LED is considered to be “transparent” when at least 50% of the radiation from the LED that impinges on the transparent layer or region emerges through the transparent region. The transparent substrate 110 may include a sidewall 110a and may also include a first (inner) face 110c adjacent the diode region 120 and a second (outer) face 110b remote from the first face 110c. In some embodiments, the second face 110b is of smaller surface area than the first face 110c. Moreover, in some embodiments, the sidewall 110a may be stepped, beveled and/or faceted, so as to provide the second face 110b that is of smaller surface area than the first face 110c. In other embodiments, the sidewall 110a is an oblique sidewall that extends at an oblique angle from the second face 110b to the first face 110c. Non-oblique sidewalls and approximately equal size faces may be also be provided in other embodiments. For example, a square or rectangular chip with straight or non-oblique sidewalls may also be used in some embodiments.

Still referring to FIG. 2a, at least a contact 160 ohmically contacts the p-type or n-type layer and extends on the first face 130a of the LED chip 130. A second contact may also ohmically contact the other of the p-type or n-type layer and also extend on the first face 130a of the LED chip 130, this structure as shown in FIGS. 2c and 2d. The device of FIG. 2a may be a lateral geometry device or a vertical geometry device may also be used. The anode and cathode contacts may directly ohmically contact the n-type layer and the p-type layer, respectively, or may ohmically contact these layers by way of one or more conductive vias and/or other intermediate layers. Moreover, as illustrated in FIG. 2c, the anode contact 160 and the cathode contact that both extend on the first face 130a are approximately flat and co-planar. In other embodiments, they may not be flat or co-planar. As also shown in FIG. 2c, the anode contact 160 and the cathode contact 160 are spaced apart from one another on the first face 130a, to define gap there between. The anode and cathode contacts 160 may be less than about 10 μm thick in some embodiments and may be less than about 5 μm thick in other embodiments.

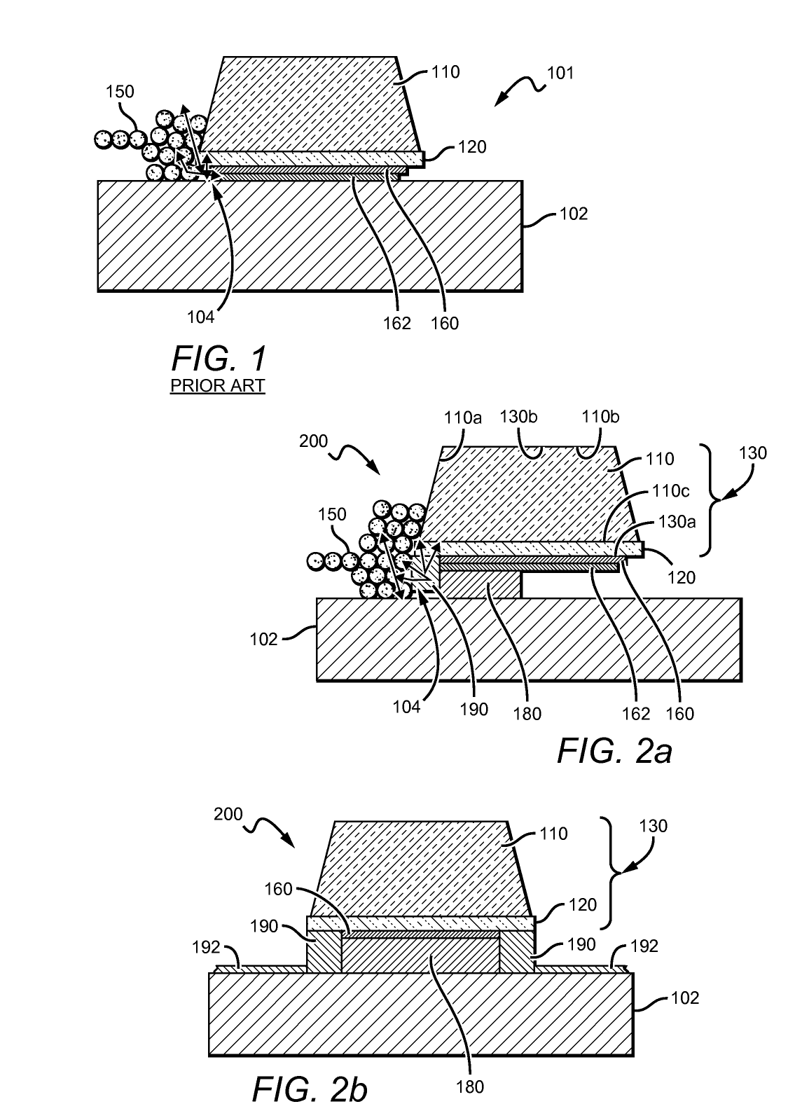

FIGS. 2a-2f also show a portion 190 which extends below surface 130a and the contacts 160. As described above, portions 190 may be a reflective layer or other structural portion, which extends below surface 130a. In some embodiments, this may be a submount or any other feature. The inclusion of portion 190 may increase output efficiency of the device as the light emitted from the area 104 between the contact pad and the edge of the device is reflected by portion 190 rather than absorbed, as shown in FIG. 1. In other embodiments, portion 190 may be a dielectric material, or a polymeric material. In yet other embodiments, portion 190 may include reflective particles in a polymeric matrix, such as a white reflective material. In other embodiments, portions 190 may include other optical elements, or other particles, such as diffusers, reflectors, and/or scattering particles. In one example, the matrix may include a conversion material, such as phosphor. In addition, portions 190 may be disposed to improve thermal conductivity. The portions 190 extending below surface 130a of FIG. 2a are a reflective layer, examples of such reflective layers include a dielectric mirror, a white reflective layer, such as a titania-filled layer, and/or other white/reflective layer. Many different reflectors can be used including a mirror layer comprising silver, diffuse reflectors, materials comprising a reflective white color, and thin film reflectors, such as metal or dielectric layers. In some embodiments the reflective layer may include a binder material. In yet other embodiments, the reflective layer may include a binder and a conversion material. In still other embodiments, the reflective layer may be a silicone based epoxy. In other embodiments, this reflective layer may have other thicknesses, including some which do not exceed the thickness of the contacts 160. Furthermore, in other embodiments, the reflective layer shown by portions 190 may also extend between the contacts 160. In embodiments where the reflective layer 190 exceeds the height of the contact pads 160, it is difficult to mount such devices as the contact pads 160 would be recessed in relation to the mount surface of the device. Therefore, it is desirable to include solder material or generate a contact bump 180 with enough material to overcome or meet the height barrier of the reflective layer. In other embodiments it may also be desirable to have a balanced amount of material on both contact pads so that uniform attachment is achieved.

Some embodiments may include a solder mask over portions of the bottom surface 130a, which do not include contact pads 160. A solder mask may comprise any material that is generally used in microelectronic manufacturing to physically and electrical insulate those portions of the circuit to which no solder or soldering is desired. Solder masks may include thermally cured screen-printed masks, dry film and/or screen-applied or curtain-coated liquid photoimageable solder masks. In some embodiments, the solder mask may comprise a conventional photoresist, or any other material that is non-wettable to solder. A solder mask may be less than about 30 μm thick in some embodiments, less than about 5 μm thick in other embodiments, and may be about 1 μm thick or less in still other embodiments. A wide range of thicknesses and materials may be used, as long as effective solder masking takes place. Moreover, in other embodiments, the solder mask may also include virtually any non-metallic coating, such as silicon dioxide and/or silicon nitride, which may be deposited by physical and/or chemical deposition techniques. In still other embodiments, the solder mask may be reflective, so as to reflect optical radiation that emerges from the diode region 120, back into the diode region 120. Examples of such reflective layers include a dielectric mirror, a white reflective layer, such as a titania-filled layer, and/or other white/reflective layer.

The devices of FIGS. 2a, 2c and 2d include a phosphor layer 150 provided on the second face 130b of the LED chip 130. The phosphor or conversion material layer 150 of FIG. 2a is shown to only extend over a portion of the device, but it should be understood that this may be disposed in other areas as well. FIGS. 2c and 2d demonstrate the phosphor layer being distributed over the light emitting device. The phosphor layer 150 may also extend onto the sidewall 110a of the substrate, onto the sidewall of the diode region 120, and/or beyond, or extending beyond the width of, the anode and cathode contacts 160. In some embodiments, the phosphor layer 150 is a conformal phosphor layer that may be less than about 150 μm thick in some embodiments, less than about 100 μm thick in other embodiments and less than about 50 μm thick in yet other embodiments. It will be understood that the term “phosphor” is used herein to denote any wavelength conversion material, and may be provided according to various configurations. Phosphor layer 150 may also be any type of functional layer or layers, such as any layer disposed to affect the properties of the emitted light, for example, color, intensity and/or direction.

Various techniques may be used to apply the phosphor layer 150, including dispensing, screen printing, film transfer, spraying, coating and/or other techniques. Phosphor preforms also may be applied. In some embodiments, the phosphor layer 150 may comprise silicone and/or other transparent material having phosphor particles therein. It will also be understood that the phosphor layer 150 is shown in FIG. 2c to be co-planar with the outer face 130a of the diode 130. However, the outer or edge portions of the phosphor layer 150 need not be co-planar with these outer faces. Specifically, it can be recessed from the outer face 130a or may protrude beyond the contacts 160.

Moreover, FIGS. 2c and 2d illustrate the phosphor layer 150 as a thin conformal layer having uniform phosphor particle density. However, a phosphor layer may be provided that comprises phosphor particles that are non-uniformly dispersed therein, and that, in some embodiments, may include a phosphor-free region at the exterior surfaces of the phosphor layer. Moreover, the phosphor layer may also be configured as a conformal and/or non-conformal layer.

The phosphor layer 150, or any wavelength conversion layer, converts a portion of the light emitted from the diode 120 to a different wavelength, a process that is known in the art. One example of this process, is converting a portion of blue-emitted light from light emitter, such as an LED chip, to yellow light. Yttrium aluminum garnet (YAG) is an example of a common phosphor that may be used.

In some embodiments, the phosphor particles comprise many different compositions and phosphor materials alone or in combination. In one embodiment the single crystalline phosphor can comprise yttrium aluminum garnet (YAG, with chemical formula Y₃Al₅O₁₂). The YAG host can be combined with other compounds to achieve the desired emission wavelength. In one embodiment where the single crystalline phosphor absorbs blue light and re-emits yellow, the single crystalline phosphor can comprise YAG:Ce. This embodiment is particularly applicable to light emitters that emit a white light combination of blue and yellow light. A full range of broad yellow spectral emission is possible using conversion particles made of phosphors based on the (Gd,Y)₃(Al,Ga)₅O₁₂:Ce system, which include Y₃Al₅O₁₂:Ce (YAG). Other yellow phosphors that can be used for white emitting LED chips include:

### Tb₃₋ₓREₓO₁₂:Ce (TAG);

RE=Y, Gd, La, Lu; and/or

### Sr_{2-x-y}BaₓCa_{y}SiO₄:Eu.

In other embodiments, other compounds can be used with a YAG host for absorption and re-emission of different wavelengths of light. For example, a YAG:Nb single crystal phosphor can be provided to absorb blue light and re-emit red light. First and second phosphors can also be combined for higher CRI white (i.e., warm white) with the yellow phosphors above combined with red phosphors. Various red phosphors can be used including:

SrₓCa₁₋ₓS:Eu,Y; Y=halide;

### CaSiAlN₃:Eu; or

### Sr_{2-y}Ca_{y}SiO₄:Eu.

Other phosphors can be used to create saturated color emission by converting substantially all light to a particular color. For example, the following phosphors can be used to generate green saturated light:

### SrGa₂S₄:Eu;

### Sr_{2-y}Ba_{y}SiO₄:Eu; or

### SrSi₂O₂N₂:Eu.

The following lists some additional suitable phosphors that can be used as conversion particles, although others can be used. Each exhibits excitation in the blue and/or UV emission spectrum, provides a desirable peak emission, has efficient light conversion:

### Yellow/Green

### (Sr,Ca,Ba)(Al,Ga)₂S₄:Eu²⁺

### Ba₂(Mg,Zn)Si₂O₇Eu²⁺

### Gd_{0.46}Sr_{0.31}Al_{1.23}OₓF_{1.38}:Eu²⁺_{0.06}

### (Ba_{1-x-y}SrₓCa_{y})SiO₄:Eu

### Ba₂SiO₄═Eu²⁺

### Red

### Lu₂O₃═Eu³⁺

### (Sr₂₋ₓLaₓ)(Ce₁₋ₓEuₓ)O₄

### Sr₂C₁₋ₓEuₓO₄

### SrTiO₃:Pr³⁺,Ga³⁺

### CaAlSiN₃IEu²⁺

### Sr₂Si₅N₈═Eu²⁺

In some embodiments, the layer 150 may be a functional layer which comprises a light scattering layer, which comprises a binder material as discussed above and light scattering particles, for example titanium oxide particles. In other embodiments, the layer comprises materials to alter the refractive index of the functional layer. In some embodiments, the functional layer comprises a combination of one or more of the types of functional layers described herein (e.g. a wavelength conversion layer and a scattering or refractive index altering layer).

In some embodiments, the diode region 120 is configured to emit blue light, for example light having a dominant wavelength of about 450-460 nm, and the phosphor layer 150 comprises yellow phosphor, such as YAG:Ce phosphor, having a peak wavelength of about 550 nm. In other embodiments, the diode region 120 is configured to emit blue light upon energization thereof, and the phosphor layer 150 may comprise a mixture of yellow phosphor and red phosphor, such CASN-based phosphor. In still other embodiments, the diode region 120 is configured to emit blue light upon energization thereof, and the phosphor layer 150 may comprise a mixture of yellow phosphor, red phosphor and green phosphor, such as LuAG:Ce phosphor particles. Moreover, various combinations and subcombinations of these and/or other colors and/or types of phosphors may be used in mixtures and/or in separate layers. In still other embodiments, a phosphor layer is not used. For example, a blue, green, amber, red, etc., LED need not use phosphor. In embodiments which do use a phosphor, it may be beneficial to provide a uniform coating in order to provide more uniform emissions.

Some devices, such as those shown in FIGS. 2c and 2d may include an outer transparent layer 156, for example, comprising silicone without phosphor particles therein, may also be provided to provide a primary optic for the light emitting device 200. The transparent layer 156 that is free of phosphor may be shaped to provide a lens, dome and/or other optical component, so that the sides and/or tops thereof may be oblique to the diode region. The transparent layer 156 that is free of phosphor may also encapsulate the phosphor layer 150 and/or light emitting surfaces of the LED chip 130. The transparent layer 156 may be at least 1.5 mm thick in some embodiments, at least 0.5 mm thick in other embodiments, and at least 0.01 mm thick in yet other embodiments, and may not be present in still other embodiments. Thus, in other embodiments, a transparent layer may be used without a phosphor layer 150. For example, the transparent layer 156 may be directly on the second face 130b of the LED chip 130. In some embodiments, a relatively thick transparent layer may be used. In other embodiments, a conformal transparent layer may be used. In still other embodiments, the transparent layer may be provided on a phosphor layer that comprises phosphor particles that are non-uniformly dispersed therein. The device may further include an additional encapsulant or lens 158, which may be silicone or glass. Other embodiments may not include this additional lens 158.

FIG. 2b is a cross-sectional view of another light emitting device 200 according to the present disclosure. The device of FIG. 2b is similar to the device of FIG. 2a; however, it includes at least two contacts (comprising contact pads 160 and contact bumps 180 and) it additionally includes a reflective material 192 on the surface of the substrate 102. The inclusion of such a material can further increase output efficiency. Having a reflective layer on both the bottom or mount surface of a device and on the submount can reduce gaps where light may be lost or absorbed. In some embodiments the reflective layer on the submount will cover the entire submount, whereas in others it may cover only a portion, such as adjacent to the chip or device. Additionally, such layers may also be used to shape the output. Substrate 102 may comprise several materials, such as but not limited to ceramic substrates and/or aluminum nitride substrates.

FIG. 2d is a cross-sectional view of a light emitting device 200. The chip 130 of FIG. 2d differs from that of FIGS. 2a-2c in that it does not include a substrate 110, but rather is just the diode 120. The substrate may have been removed prior to the device being placed on an adhesive or glass layer for further processing.

The devices of FIGS. 2a-2f can also be manufactured as components integrated into other electronic devices. As such, the devices may need to be mounted or connected to a substrate, such as substrate 102, which can comprise an electronic element, for example a PCB. However, as it can be noted from FIGS. 2a-2f, the contact pads 160, and in some embodiments bond metals 162, are recessed from the mounting surface 130c or the lowest point of the mounting surface of the device 200. Though it is possible to provide a massive amount of mounting paste on the mounting surface or PCB that the device is to be mounted to, to reach recessed contacts, this does not ensure that a connection will be made to the mounting pads 160, resulting in low yields, and this may also result in different amounts of paste being disposed on the different contact pads 160 causing an unbalanced or crooked mount. Instead, it is preferable to include contact bumps 180.

FIG. 2e is a cross-sectional view of a light emitting device 200, another embodiment according to the present disclosure. Features similar to those found in previous figures are referred to by the same numerals for ease of reference. The chip 120 of FIG. 2e differs from that of FIG. 2d in that it is a vertical device. Therefore, the device has a singular bottom contact 204 and a top contact 206. Additionally, it may include a conductive growth substrate (not shown) or instead the diode region may be bonded to a conductive carrier substrate, such as those described above. Also, the chip 120 of FIG. 2e is a different geometry than that of FIG. 2d. However, it should be noted that a chip of any shape may be utilized. The device 200 of FIG. 2e may include a conversion material and encapsulant over the chip 120, but other embodiments may not include these.

FIG. 2f is a cross-sectional view of a light emitting device 200, another embodiment according to the present disclosure. The chip 120 of FIG. 2f differs from that of FIG. 2d in that it may be a lateral device with top-side contacts; for example, both contacts 214, 216 of the device are on a surface opposite that of the mounting surface. Therefore, the device has a bottom contact, mounting or die attach pad 212 which is used to attach the device 200 to a mounting surface. The mounting pad or die attach pad 212, in some embodiments, is not electrically connected to the chip 120. In some embodiments, the die attach pad may serve to provide a thermal path to improve heat efficiency of the device. Additionally, the device may include a conductive or insulating growth substrate (not shown) or instead the diode region may be bonded to a carrier substrate, such as those described above. The device 210 of FIG. 2f may include a conversion material and encapsulant over the chip 120, but other embodiments may not include these. It should be noted that any size or shape diode region or chip may be utilized. In yet other embodiments, a vertical device may be utilized with a top contact, bottom contact, and additionally at least one bottom mounting pad or die attach pad.

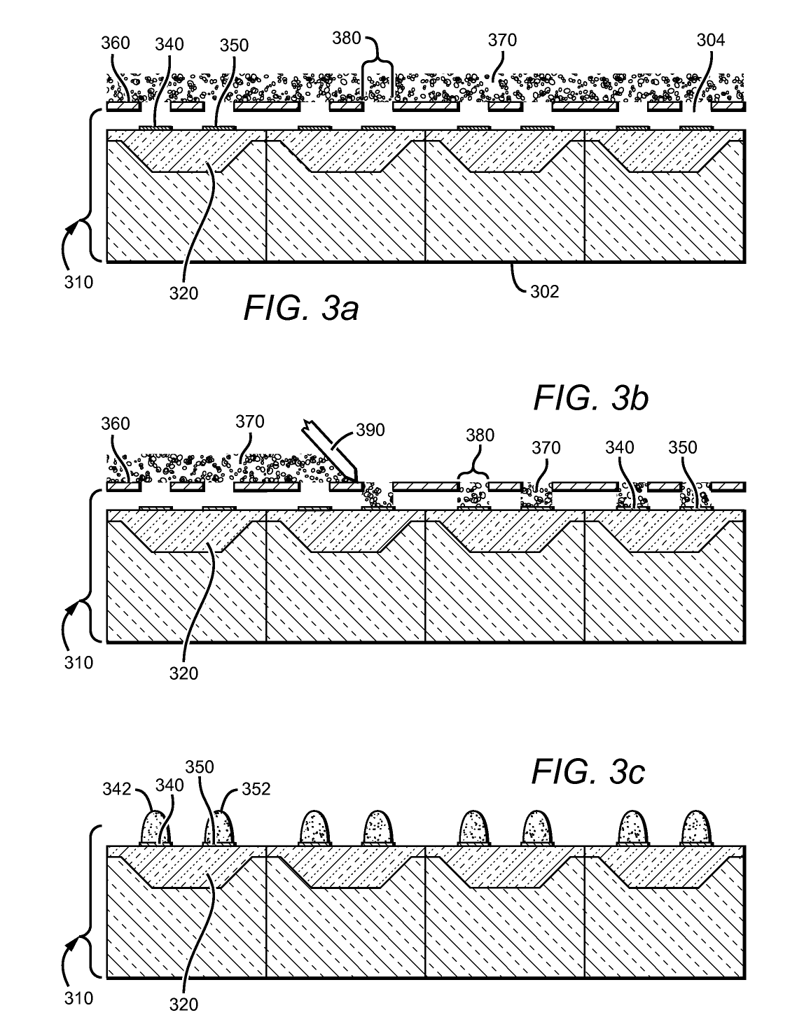

FIGS. 3a-3c show one embodiment of a method for providing contact bumps 342, 352 over the contact pads 340, 350, such that the contact bumps 342, 352 protrude beyond the lowest point of the mounting surface. Though the figures show 4 devices in the array, it is understood that a wafer or virtual wafer could include many more devices.

FIGS. 3a-3c are cross-sectional views of an array of devices arranged for wafer level processing. Wafer level processing may also refer to virtual wafers. In FIG. 3a, an adhesive, such as a tape based adhesive, is deposited and/or laminated on the top surface 302 of the array of devices. Optionally the adhesive may be placed on a carrier wafer, for example, a substrate commonly used in the art for mounting LED chips, such as a sapphire or silicon carbide substrate. This allows for the formation of a “virtual wafer” in which an array of LED dies can be deposited thereon. It is understood that the use of a carrier wafer is optional and provides the advantage of improving the structural integrity for the array; however, the virtual wafer may be created without the carrier wafer. Virtual wafers and integrated phosphors have been disclosed in a copending U.S. patent application Ser. No. 14/053,404, filed Oct. 14, 2013, by Heikman et. al entitled “CHIP WITH INTEGRATED PHOSPHOR,” assigned to CREE, Inc. The disclosures of this application are hereby incorporated by reference. Furthermore, the devices may be attached as shown in FIGS. 3a-3c or may be spaced apart.

FIG. 3a shows an array of devices 310, each device includes a diode or active region 320 and contact pads 340. As described with relation to FIGS. 2a-2f, the lowest point of the mounting surface 304 may be a reflective layer which is disposed on the bottom or mounting surface, therefore, the contact pads 340, 350 are recessed in relation to the plane of the mounting surface 304 of the device 310 after the reflective layer is applied (not shown in FIGS. 3a-3c), as this reflective layer may exceed in thickness compared to the contact pads. In order to form the contact bumps 342, 352, (FIG. 3c) a stencil 360, shown in FIGS. 3a and 3b, is provided over the mounting surface 304 over the array of devices 310, such that the stencil has openings aligned with and over the contact pads 340, 350. The stencil is shown spaced away from the surface 304; however, it is understood that a space is not necessarily required. This stencil may be made of any material which can withstand the material deposition process, such as metal. The process of providing the contact bumps only requires one alignment step which is the alignment of the stencil 360 over the contact pads 340, 350. An electrically conductive or solder material 370 is provided over the stencil.

FIG. 3b shows the array of devices 310 of FIG. 3a while the material 370 is being distributed through the openings 380 into the areas over the contact pads 340, 350. The desired material for the contact bumps, any electrically conductive material 370, is provided over the stencil 360 and devices 310. In some embodiments this electrically conductive material 370 may be a solder material, such as a lead free alloy. In other embodiments, this material may be provided as a paste. In yet other embodiments, this material is one which, when melted, only wets to the contact pads 340, 350. This electrically conductive material 370, is then provided in the openings 380 in the stencil over the contact pads 340, 350.

As shown, a blade or squeegee 390 may be used to evenly distribute the material 370. The blade 390 is passed over the surface of the stencil 360 forcing an equal amount of material 370 through the openings 380 and into the cavities below over the contact pads 340, 350. This material may also fall around the contact pads 340, 350; however, the material will gather over the contact pads 340, 350 during the reflow process. The amount of material 370 which enters the cavity through openings 380 can be adjusted by varying the thickness of the stencil, size of the openings 380, amount of material provided over the stencil, and by changing the speed and pressure with which the blade distributes the material.

After the material 370 is distributed in the cavities 380 over the contact pads 340, 350, the stencil 360 may be removed and the devices 310 undergo a reflow process. The bumping or solder material does not need to be placed neatly over only the contacts, as the material will move together and only bond with the contact pads during reflow. However, if the amount of material is in great excess or not adjusted correctly, some contact bumps may bridge and form a singular short circuited contact. In order to prevent such bridging, the amount of material disposed must be reduced, disposed at the accurate amount, and/or a solder dam may be placed between the contacts. Though the solder dam is not necessary, as the amount of material may be adjusted instead, a dam may be used. For example, barriers or solder dams of any type may be used.

During the reflow process, the material 370, or solder, gathers on the contact pads 340, 350 and attaches to the contact pads 340, 350 bonding together. The surface tension of the solder bump forms the contact bumps 342, 352 over and in contact with the contact pads 340, 350. These contact bumps 342, 352 may protrude beyond the height of a later applied reflective layer or may only protrude partially through the thickness of a reflective layer. These contact bumps 342, 352 can now be used to mount to any mount surface or device and create an electrical connection to the device 310. Therefore, the devices 310 may now be mounted to any surface or device and an electrical connection can be reliably made. The contact bumps 342, 352 can be attached to bare wires, printed circuit boards, or any type of submount, such as ceramic, metal core, etc. Thereby, the devices themselves are bumped and ready to be attached to a larger variety of systems, rather than bumping the surface that the devices will attach to. Additionally, the devices are bumped at the wafer, not package level, providing increased efficiency and requiring only a single alignment step. However, if desired, the devices may be bumped similarly at the package level as well.

Embodiments of the method described in relation to FIGS. 3a-3c can also allow for the placement of equal amounts of material on each contact pad. This allows for balanced devices, which are more reliable when mounted. In other embodiments, with other configurations, such as contacts which are not co-planar, it may be desirable to provide different amounts of material. This may be accomplished by providing a stencil with different sized openings. The process shown in FIGS. 3a-3c may be a low cost process, as it can use existing tools and material systems. Bumping by this process may also reduce solder bridging on the order of 100-300 microns. In other embodiments, rather than using a stencil and squeegee, the contact bump material may be distributed as preforms or through solder ink jetting techniques. After bumping, a reflective layer may be added.

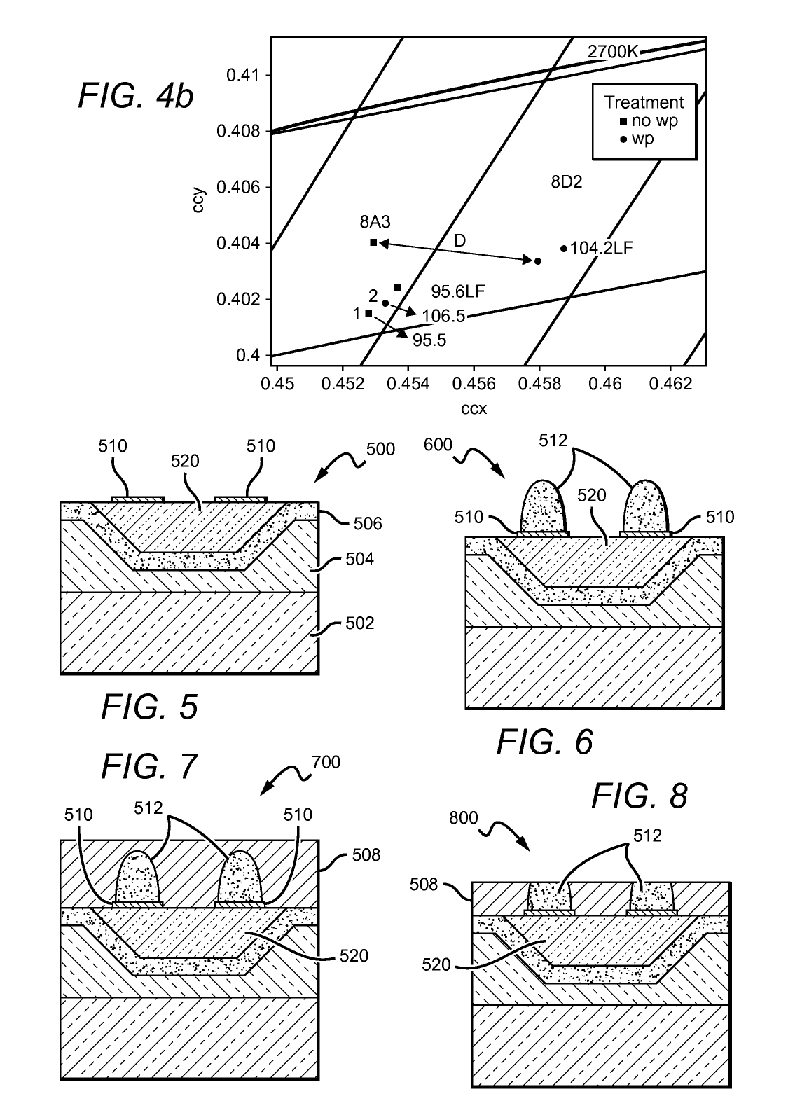

Inclusion of the reflective material 190 may be significant in increasing emission efficiency or the lumens per watt (LPW) of a device. This may be especially significant in embodiments, which do not have a submount or substrate below the device. In these embodiments, the use of a reflective layer or material can increase the LPW such that the device with the submount and the submount free device, though differing in physical size as the submount free device may be smaller, can have the same LPW output. The same device without the reflective layer can lose up to 30% of device efficiency. FIGS. 4a and 4b show exemplary LPW improvements for devices with a reflective layer (wp) and those without (no wp). As shown in FIG. 4a, improvements of 5-10 LPW were recorded. FIG. 4b shows similar gains between points 1 and 2, while maintaining a same or similar color output. These experimental measurements demonstrate 5-10.2% LPW gains between devices without and with the reflective layers demonstrated in FIGS. 2a-2f. In yet other embodiments, gains of up to 12% have been shown with the use of a reflective layer compared to devices which do not have such a reflective layer.

The addition of the reflective layer before the formation of the contact bumps is possible and may be used, but this method may require additional steps of alignment, especially at the edges of devices and near contact pads. Alternately, the reflective layer may be added to the devices after the contact bumps are formed, as shown in FIG. 3c. FIGS. 5-8 demonstrate the steps of providing contact bumps and a reflective layer for such devices, according to an embodiment of the present disclosure. FIG. 5 is a side view of a device 500 with recessed contact pads 510. The device includes a glass lens 502 and silicon encapsulant 504; however, these may not be required in all embodiments. The lens or encapsulant may be shaped using roughening, dicing, etching elements, molding or may be preshaped, a partial hemisphere, or may include concentric rings. Though the current shape is square or rectangular, any shape is appropriate, and any light extraction features may be used. The device 500 includes a wavelength conversion material 506, diode or light output region 520. In some embodiments, the light output region 520 may be inclusive of a substrate (not shown).

FIG. 6 shows a similar device 500 with contact bumps 512 formed over the contact pads 510 such that the device may be mounted to a mounting surface and electrical contact can be made with the contact pads and the mounting surface, through the contact bumps 512.

FIG. 7 shows another embodiment of a device 700 according to the present disclosure. The device also includes a reflective layer 508 over the original mounting surface and surrounding the contact bumps, which raises the height of the surface adjacent to the mounting area, thereby recessing the contact pads 510. The reflective layer now forms a portion of the mounting surface and covers at least the perimeter of the surface. In some embodiments layer 508 may cover the entire original mount surface, while in others it may not cover the contact pads or the area between the contact pads. The reflective layer 508 may be provided by flooding, screen stenciling, screen printing, spraying, doctor blade, pressing the device or wafer into the paint, spinning and/or squeegeeing. In some embodiments a solvent may be added to provide a shrinkage effect so the reflective layer will recess below contact bumps after curing, as shown in FIG. 16. The reflective layer fill process can be accomplished by using a basic coating tool without the need for high accuracy alignment, translating to lower equipment costs, higher yields and increased throughput.

This device 700 includes the reflective layer 508 over and surrounding all areas around and between the contact pads 510 and bumps 512. Next, as shown in FIG. 8, the device may be polished or ground to create an even surface and expose the contact bumps 512. Grinding may be completed by sand paper for localized grinding. Alternately, micromachining or a grinder may be used, such as by employing a fine grind with a controlling grit. Additionally, chemical processes may be used to expose the contact bumps 512, such as a chemical mechanical process (CMP) or polishing using a solvent. It should be noted that in other embodiments, the device may be at the chip, die, or wafer level and not yet include a phosphor layer, encapsulants or lenses. In such cases, the reflective layer may be added before these components, at the wafer level. The device could then subsequently be placed on a substrate, if desired, and undergo additional steps.

In some embodiments, the process shown in FIGS. 3a-3c may be repeated after the product or device shown in FIG. 8 is completed. For example, a second solder bumping process may be executed, which applies an amount of material, sometimes small, so the bump will protrude slightly past the reflective or white paint material. In some embodiments, the use of the term white paint material is in reference to a white reflective material, which provides a desired light extraction, such as reflectivity of greater than 80% or in some cases in the range of 90-94%. White reflective materials such as these, in some embodiments, may be a material having a high refractive index material loaded in a silicone. This material does not act as a surface reflector, instead allowing light to enter the material and interact with the particles therein, such that these interactions bend the light to reflect away. One advantage of using such a material is that this type of light interaction, because it bends light rather than reflects light directly back, allows for light to be fanned or bent away, such that less light may be absorbed when directly reflected. One example of such a white material provides a balance, such that the loading/spatial-density of the high refractive index material in an index-matched silicone, results in the desired light extraction to be an effective reflective layer. Thicknesses of such materials may vary based on the amount of material loaded in the silicone. In some embodiments, these white reflective materials may have thicknesses higher than those of traditional reflectors, such as thicknesses greater than 20 μm or between 25-200 μm. This may result in improved attach yields. It should also be noted that in some embodiments, the processes shown in FIGS. 5-8 may be carried out on a separate substrate or submount, which can then be attached to or coupled with a chip or device, such that the contact pads of the device are electrically connected to the contacts on the submount. This is shown in FIG. 17, where a device 1700 shows a chip 1730 attached to a submount 1702. The submount 1702 has been prepared as shown in FIGS. 5-8 to include one or more contacts 1712 surrounded by the reflective material 1708. After the submount is prepared, a chip 1730 may be mounted to the submount 1702, connection being made through one or more contacts 1712 to the anode and/or cathode of the chip, and the device 1700 may then be placed in or mounted to any other device or surface.

Using the methods disclosed herein, the contacts and reflective layer can be placed in a repeatable mass process. Performing the bumping process first ensures the highest yield compared to adding the reflective layer first as misalignments or bleed-in can impact the ability to bump the device. Additionally, the process allows for equal amounts of metal to be placed, which also improves reliability and the device will not be unbalanced. Also, taller solder joints, due to bumping, offer higher solder joint reliability by better absorbing strains generated during thermal expansion mismatch, due to temperature excursions, during operational life. Higher optical efficiency is achieved as all optically relevant areas are covered by the reflective material or ink leading to minimized light leakage from the contact side, resulting in higher efficiency. Also, the grind process leads to a planar surface which would ease wafer/device handling, assessment and pick-up off of tape, as the device will be more reliably flat on the tape, not tilted which causes inaccuracies in assessment of the device and pick-up. A more reliably flat device will allow for more accurate determination of the devices center, allowing the placement system to operate more accurately and reducing the need for extra calculations after the fact to compensate for inaccuracies caused by tilted devices.

As stated previously, the amount of material disposed over the contact pads may be adjusted by changing the stencil thickness, aperture size, and speed or force with which the blade is moved over the stencil. Therefore a variety of different combinations of these measurements may be able to provide the desired result. Additionally, the desired result may vary on device size and application of the device. In an exemplary embodiment, a device with the size of 500 microns is in use. This device may have a reflective layer of 25-50 microns, though other devices may have layers which are less than 25 microns, or greater, such as up to 125 microns. For such a device, a stencil thickness in the range of 25-50 microns may be used. A stencil of 25 microns in thickness may be preferred. The force of the blade for this configuration may range from 50 gms force to 5000 gms force. However, it is understood that these are exemplary ranges and that any set of numbers may be used to achieve the desired result.

After the device is polished or ground such that the contact bumps are exposed for connection, as shown in FIG. 8, the device or wafer is ready for subsequent processing, such as backend steps including testing. If the devices are in a wafer, they may now be singulated and sorted. Singulation may be accomplished by blade, bevel cut, bevel cut blade, laser, scoring and breaking, or any other appropriate singulation process. In some embodiments, it may be advantageous to perform the break operation at an elevated temperature so that silicone will tear easily during the break. It may also be helpful to use a knife blade on the backside of the device prior to break to pre-scribe the reflective layer. A thin blade may then be used to cut the remaining portion of the device. After singulation the device may be mounted to any mount surface or substrate. If desired a solder paste may be placed between the exposed contact bumps and the mount surface connections.

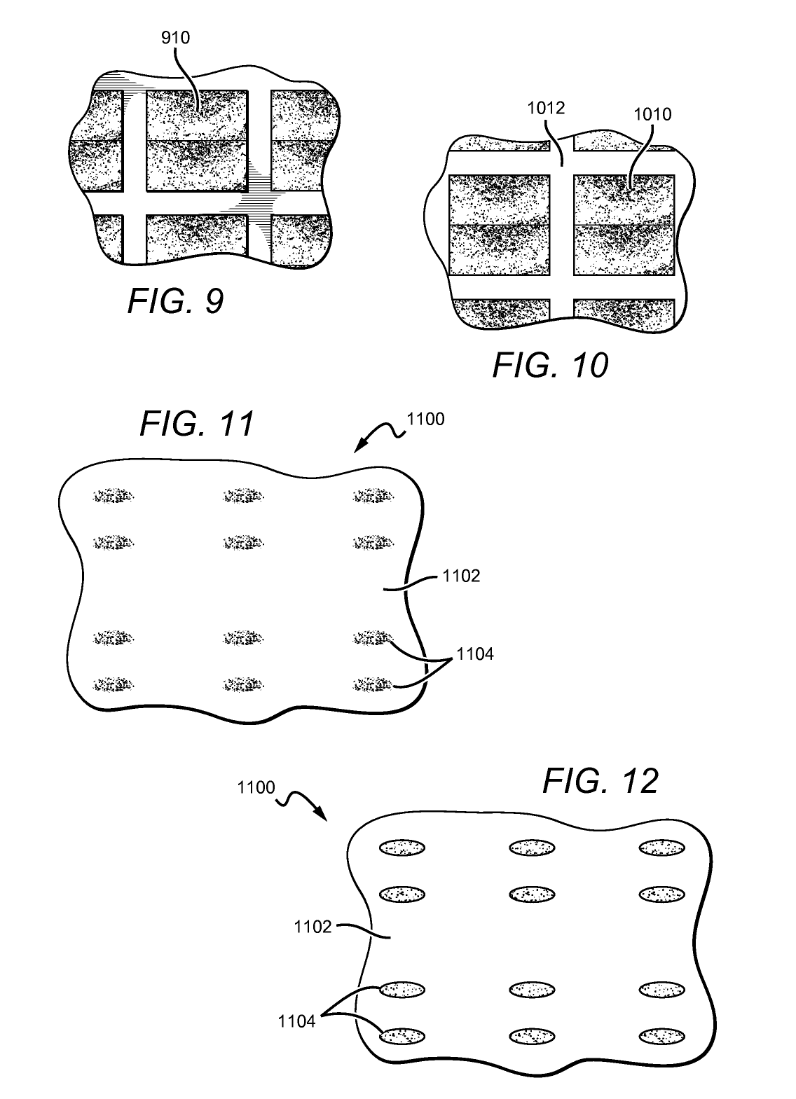

FIGS. 9 and 10 are exemplary bottom views of a wafer of devices according to an embodiment of the present disclosure. FIG. 9 is a bottom view of a device similar to that of the wafer of devices shown in FIG. 3c, such that the device includes contact bumps 910 on the bottom surface, or surface adjacent to the mounting surface. The wafer of FIG. 9 does not yet include a layer of reflective material. The wafer of FIG. 10 is similar to that of the one shown in FIG. 9, except the wafer of FIG. 10 includes the white reflective layer 1012 surrounding contact bumps 1010.

FIG. 11 is a top view of a wafer of devices 1100 according to one embodiment of the present disclosure. The wafer has undergone the steps of forming and reflowing of the contact bumps 1104 and the flooding or coating of the device with the reflective layer 1102, such that the contact bumps 1104 are slightly obscured or covered by the reflective layer 1102. In other embodiments, the amount of reflective material may be less or more, impacting the amount of the contact bump which is covered or surrounded. Though this embodiment shows the entire mount surface coated or covered by the reflective material, it is understood that the reflective layer may also be disposed in only desired areas, such as only disposed between the contact pads. This may be advantageous in various embodiments to control or shape emissions in a desired manner. In other embodiments, the reflective layer may be disposed on one side of each device. The reflective layer may be disposed on any portion of the device. Additionally, as shown in FIGS. 2a-2f, the devices may have any number of contacts on the bottom surface. In yet other embodiments, more than two contacts may be utilized.

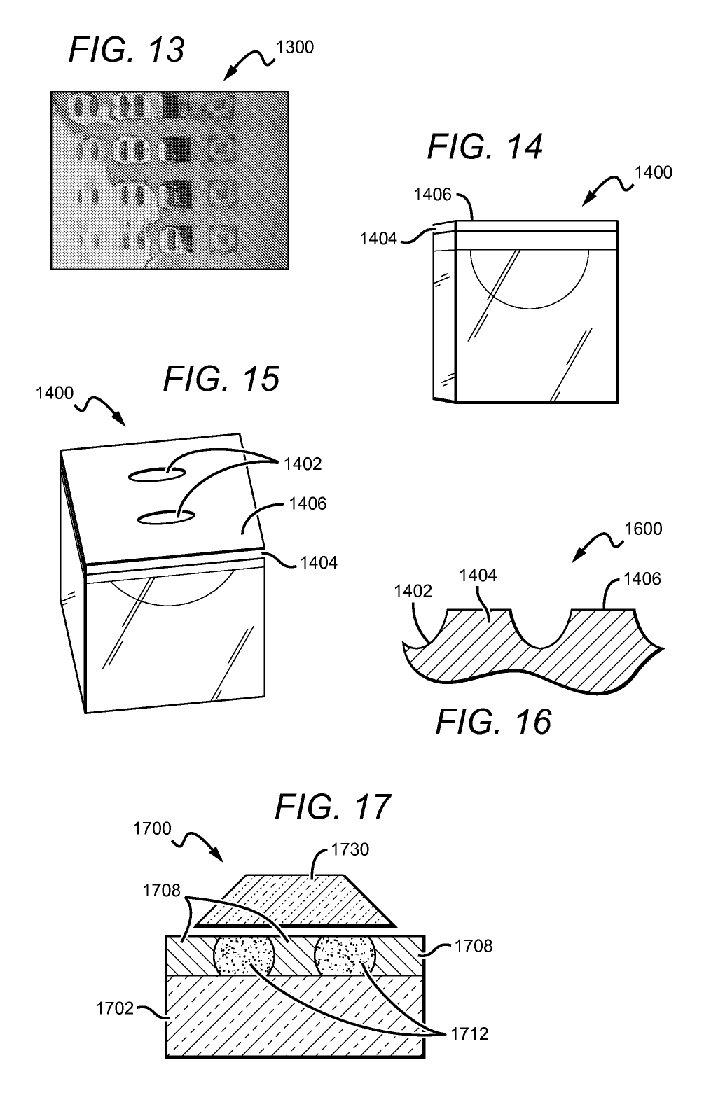

FIG. 12 shows the wafer of devices 1100 of FIG. 11 after the wafer has undergone the grinding or polishing step, such that the contact bumps 1104 are now clearly exposed, while still surrounded by reflective material 1102. FIG. 13 is a top view of a wafer of devices 1300 according to one embodiment of the present disclosure. Wafer 1300 is progressively ground from the left side to the right side to demonstratively expose all the layers of the device. As it can be seen from the image, the lower left side shows the wafer of devices covered by the reflective layer, with contacts barely visible, whereas the top right of the image shows the entire device ground down.

FIGS. 14 and 15 show various views of a device 1400 according to the present disclosure, which includes bumped contacts 1402 and a reflective layer 1404, such that the device is ground to expose the contacts and provide a substantially planar or flat mounting surface 1406. FIG. 14 is a side perspective view, while FIG. 15 is a top perspective view of the same device. As it can be seen, area 1406 is the mounting or bottom surface of the device, with the remainder of the device, including light emission regions and encapsulants, below the white or reflective layer 1404. Though FIGS. 14 and 15 show devices 1400 with flat or planar mounting surfaces, it is also possible to use the processes described above to have a device 1600 with a mounting surface 1406 shaped as shown in FIG. 16, such that the contact bumps are raised in relation to the remainder of the mount surface. Here, the reflective layer 1404 surrounds the contacts 1402 but does not entirely cover them, creating an uneven surface with the contacts 1402 protruding, such that the contacts 1402 are the lowest point of the mounting surface. In other embodiments, it may be preferable to have a flat mounting surface, as those of FIGS. 14 and 15, to improve device handling, mounting, placement, assessment and picking. The device of FIG. 16 may be ground further to achieve the planar surface of FIG. 14, if desired.

As stated, the processes and methods described above may be applied to devices, packages, or unprepared dies or wafers. In other words, the device may already include conversion layer and encapsulants before the bumping, coating and grinding steps, or the device may still be in wafer form and back side processing including the addition of conversion materials, lenses, encapsulants, testing, or other components or processes may be applied after the bumping, coating and grinding process.

As described above, in some embodiments, these devices with the planar mount surface with exposed or protruding contact bumps may be mounted to a surface such as a submount or printed circuit board, wherein the diode region 520 of FIG. 5 faces the printed circuit board and is connected to the printed circuit board without an intervening submount or interposer between the diode region 520 and the printed circuit board. The printed circuit board may include any conventional printed circuit board material that is used to mechanically support and electrically connect electronic components using conductive pathways, tracks or signal traces. The printed circuit board may comprise laminate, copper-clad laminates, resin-impregnated B-stage cloth, copper foil, metal clad printed circuit boards and/or other conventional printed circuit boards. In some embodiments, the printed circuit board is used for surface mounting of electronic components thereon. The printed circuit board may include multiple light emitting devices or any other device, thereon, as well as one or more integrated circuit chip power supplies, integrated circuit chip LED controllers and/or other discrete and/or integrated circuit passive and/or active microelectronic components, such as surface mount components thereon.

A printed circuit board may include an anode pad and a cathode pad. The anode pad and cathode pad providing connection surfaces of the printed circuit board, such that said surfaces and pads would connect to the contact bumps 512 of the devices directly or via a solder material. Solder layers of the printed circuit board or the device may comprise eutectic gold/tin solder, in solder bump, solder paste and/or solder preform form, and may also include other solder compositions, such as lead/tin solders, tin/silver/copper solders, known as “SAC” solder and/or other solder configurations.

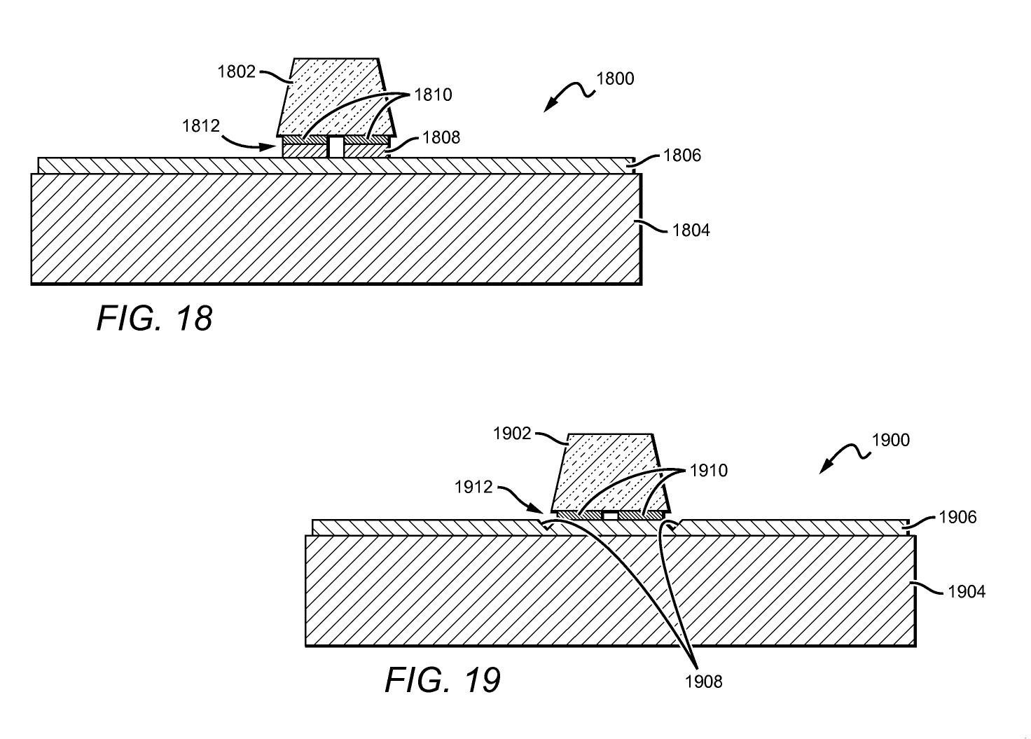

FIGS. 18 and 19 show cross-sectional side views of alternative embodiments, which allow for the placement of a white reflective material under the chip or between the chip and mounting surface or substrate. FIG. 18 shows a device 1800 with a light emitter 1802 mounted to a substrate 1804. Substrate 1804 includes a conductive trace 1806. The light emitter 1802 includes contacts 1810 on a bottom surface. Contact extensions 1808 are placed on the contacts 1810 to build up the size of the contacts 1810. These contact extensions 1808 may be bumped or electroplated on the device. The use of the extensions creates a gap 1812 between the emitter 1802 and the trace 1806 or substrate 1804, which can be filled by a white reflective material, or other reflective material. The reflective material may be applied by any known means, such as dispensing or flowing.

FIG. 19 is a cross-sectional view of another embodiment which allows the placement of a reflective material between a chip and mounting surface. FIG. 19 shows a device 1900 with a light emitter 1902 mounted to a substrate 1904. Substrate 1904 includes a conductive trace 1906. The light emitter 1902 includes contacts 1910 on a bottom surface. The area of the conductive trace 1906 just outside of the portion in contact with the contacts 1910 includes a trenched portion 1908. These trenches 1908 create a gap 1912 between the emitter 1902 and the trace 1906 or substrate 1904, which can be filled by a white reflective material, or other reflective material.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments described herein, and of the manner and process of making and using them, and shall support claims to any such combination or subcombination.

In the drawings and specification, there have been disclosed embodiments of the invention and, although specific terms are employed, they are used in a generic and descriptive sense only and not for purposes of limitation, the scope of the invention being set forth in the following claims.

We claim:

1. A surface mount device, comprising:
a reflective layer, wherein said reflective layer composes at least a portion of a mounting surface;
one or more contact pads on the device, such that the contact pads are recessed in relation to the reflective layer; and
contact extensions formed on the contact pads, the contact extensions protruding beyond the contact pads, wherein the contact extensions compose at least a portion of said mounting surface.

2. The surface mount device of claim 1, wherein said mounting surface is substantially planar.

3. The surface mount device of claim 1, wherein the mounting surface is composed entirely of the reflective layer and exposed portions of the contact extensions.

4. The surface mount device of claim 1, wherein said reflective layer comprises a white reflective material.

5. The surface mount device of claim 4, wherein said reflective layer has a thickness in the range of 25-200 microns.

6. The surface mount device of claim 1, wherein said reflective layer surrounds said one or more contact extensions.

7. The surface mount device of claim 1, wherein said reflective layer is between said one or more contact pads.

8. The surface mount device of claim 1, wherein said reflective layer has a thickness in the range of 5-200 microns.

9. The surface mount device of claim 1, wherein said contact extensions comprise a solder material.

10. The surface mount device of claim 9, wherein said solder material comprises a lead free alloy.

11. The surface mount device of claim 1, wherein said surface mount device is a light emitting device.

12. The surface mount device of claim 11, further comprising an integrated wavelength conversion material.

13. The surface mount device of claim 11, further comprising an integrated encapsulant.

14. The surface mount device of claim 13, wherein said encapsulant comprises glass.

15. The surface mount device of claim 13, wherein said encapsulant comprises silicone.

16. The surface mount device of claim 13, wherein said encapsulant is shaped to impact light emission.

17. The surface mount device of claim 11, wherein said light emitting device further comprises a light emitting region.

18. The surface mount device of claim 17, wherein said contact pads are on said light emitting region.

19. The surface mount device of claim 17, wherein a reflective layer is on said light emitting region, such that said reflective layer comprises a portion of said mounting surface and protrudes beyond said contact pads.

20. The surface mount device of claim 1, wherein said contact extensions are substantially the same size.

21. The surface mount device of claim 1, wherein said mounting surface of said device is capable of being mounted to a submount via the contact extensions and wherein an electrical connection is made through said contact extensions.

22. The surface mount device of claim 17, wherein at least one of said contact pads are electrically connected to said light emitting region.

23. The surface mount device of claim 17, wherein at least one of said contact pads are electrically isolated from said light emitting region.

24. The surface mount device of claim 17, wherein an electrical connection is made through said extensions.

25. A light emitting device chip, comprising:
a reflective layer, wherein said reflective layer composes at least a portion of a mounting surface; and
at least a contact that extends through said reflective layer, said contact comprising an exposed surface, wherein said exposed surface is co-planar with said mounting surface.

26. The light emitting device chip of claim 25, wherein said contact comprises a contact pad and a contact extension.

27. The light emitting device chip of claim 26, further comprising:
one or more contact pads on the device, such that the contact pads are recessed in relation to said exposed portion of the reflective layer; and
contact extensions formed on the contact pads, the contact extensions protruding beyond the contact pads, wherein the contact extensions compose at least a portion of said mounting surface.

28. The light emitting device chip of claim 25, wherein said mounting surface is an external surface of said chip.

29. The light emitting device chip of claim 25, wherein said reflective layer is a coating.

30. The light emitting device chip of claim 25, wherein the mounting surface is composed entirely of the reflective layer and exposed portions of the contacts.

31. The light emitting device chip of claim 25, further comprising:
a light emitting region;
a substrate on said light emitting region; and
wherein the reflective layer is on said light emitting region, such that said reflective layer is on a side of the light emitting region opposite said substrate.

32. The light emitting device chip of claim 25, wherein said mounting surface of said chip is capable of being mounted to a submount via the contacts and wherein an electrical connection is made through said contacts.

33. The light emitting device chip of claim 25, wherein said reflective layer surrounds said one or more contacts.

34. The light emitting device chip of claim 25, wherein said reflective layer comprises a white reflective material.

35. The light emitting device chip of claim 34, wherein said reflective layer has a thickness in the range of 25-200 microns.

36. The light emitting device chip of claim 25, wherein an electrical connection is made through said contacts.

37. A method of fabricating a light emitting device chip, comprising:
providing a light emitting device;
forming at least one contact on a surface of said device;
providing a reflective material on said surface of said device, said reflective material at least partially covering said surface and at least partially surrounding said at least one contact, wherein the exposed surface of said reflective material which is parallel to said surface forms at least a portion of a mounting surface; and
processing said at least one contact and said reflective material to expose at least a portion of each of said at least one contact and said reflective material, such that the exposed portions of said at least one contact and reflective material compose the mounting surface.

38. The method of claim 37, wherein said device comprises at least a contact pad on a surface of said device wherein said at least one contact pad is recessed in relation to at least a portion of said mounting surface, and wherein said at least one contact is comprised of a contact extension on said at least one contact pad.

39. The method of claim 38, wherein forming said contact further comprises:
providing a stencil over a plurality of said devices;
providing a solder material over said stencil; and
disposing said solder material over said contact pads, such that at least a portion of said solder material is in contact with said contact pads.

40. The method of claim 38, wherein said at least one contact extension protrudes beyond said surface.

41. The method of claim 39, wherein said disposing comprises passing a blade over said stencil.

42. The method of claim 37, wherein said providing reflective material comprises at least one of screen printing, spraying, and/or application by blade.

43. The method of claim 38, wherein said forming comprises reflowing the device to form a solder material into said contact extension.

44. The method of claim 39, in which the stencil has a thickness of 25 microns.

45. The method of claim 39, further comprising aligning openings in said stencil over the contact pads.

46. The method of claim 39, further comprising removing said stencil after disposing said material.

47. The method of claim 37, in which processing includes at least one of planarizing, grinding, polishing, sanding, and/or chemically processing.

48. The method of claim 39, further comprising singulating said devices.

49. The method of claim 37, wherein said device comprises a light emitting region.

50. The method of claim 49, wherein said at least one contact is electrically connected to said light emitting region.

51. The method of claim 49, wherein said device further comprises a substrate on said light emitting region, in which said reflective material is on a side of said light emitting region opposite said substrate.

52. The method of claim 37, wherein said device is capable of being mounted to a submount via the contacts and wherein an electrical connection is made through said contacts.

53. The method of claim 37, wherein said reflective material comprises a white reflective material.

54. The method of claim 53, wherein said reflective material has a thickness in the range of 25-200 microns.

55. The method of claim 37, wherein said reflective layer is between said contacts of each device.

56. The method of claim 37, wherein said reflective layer is at least partially surrounding said at least one contact of said device.

57. The method of claim 37, wherein said reflective material has a thickness in the range of 5-200 microns.

58. The method of claim 37, wherein said reflective material includes titanium dioxide.

59. The method of claim 37, wherein said reflective material is a dielectric.

60. The method of claim 37, wherein said reflective material is white.

61. A method of fabricating light emitting device chips, comprising:
providing a light emitting device, said device comprising;
at least a contact pad on a surface of said device;
disposing a solder material over said contact pads;
forming said material into contact bumps in contact with said contact pads, said contact bumps protruding beyond said surface; and
providing a reflective material at least partially covering said surface and at least partially surrounding said contact bumps, wherein said reflective material forms at least a portion of a mounting surface, further wherein said contact pads are recessed in relation to at least a portion of said mounting surface.

62. A light emitting device, comprising:
an LED chip on a submount;
a white reflective material between said chip and said submount; and
a white reflective material on the submount surrounding said chip.

63. The device of claim 62, further comprising a conductive path from the submount to the chip, through white reflective material.

64. The device of claim 63, in which said conductive path is formed by at least a contact.

65. The device of claim 63, wherein the at least one contact is at least partially surrounded by said reflective material, in which reflective material is between said contacts.

66. The device of claim 62, wherein said white reflective layer has a thickness in the range of 5-200 microns.

67. The device of claim 62, wherein said LED comprises a light emitting region and a substrate on said light emitting region, wherein said white reflective material is on a side of light emitting region opposite the substrate.

68. The device of claim 62, wherein said white reflective material comprises a portion of a mounting surface of said LED.

69. The device of claim 68, wherein said mounting surface is planar.
